(19) United States
(12) Patent Application Publication
(10) Pub. No.: US 2021/0090903 A1
(43) Pub. Date: Mar. 25, 2021

(54) METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Tatsuo Fukuda, Hakusan Ishikawa (JP); Daisuke Mizumaki, Hakusan Ishikawa (JP)

(21) Appl. No.: 16/814,151

(22) Filed: Mar. 10, 2020

(30) Foreign Application Priority Data
Sep. 20, 2019 (JP) 2019-171013

(51) Int. Cl. H01L 21/48; H01L 23/492; H01L 23/00

(52) U.S. Cl. CPC H01L 21/4875; H01L 2224/92247; H01L 24/29; H01L 24/32; H01L 24/73; H01L 24/83; H01L 24/92; H01L 2224/29084; H01L 2224/29111; H01L 2224/29139; H01L 2224/32245; H01L 2224/32502; H01L 2224/73265; H01L 2224/8322; H01L 2224/83805; H01L 23/492

(57) ABSTRACT

A method for manufacturing a semiconductor device includes forming a bonding layer on a back-surface of a semiconductor element, mounting the semiconductor element on a base member, and bonding the semiconductor element to the base member by pressing the semiconductor element on the base member. The bonding layer includes tin. The base member includes a plating layer that includes silver and tin. The base member is heated at a prescribed temperature. The semiconductor element is placed on the base member so that the bonding layer contacts the plating layer on the base member.

### CROSS-REFERENCE TO RELATED APPLICATIONS

This application is based upon and claims the benefit of priority from Japanese Patent Application No. 2019-171013, filed on Sep. 20, 2019; the entire contents of which are incorporated herein by reference.

### FIELD

Embodiments relate to a method for manufacturing a semiconductor device.

### BACKGROUND

In a manufacturing process of a semiconductor device, the semiconductor element is mounted on a base member such as a copper frame via a bonding member. In this process, when the bonding surface of the semiconductor element has low affinity for the bonding member, the bonding strength is reduced between the semiconductor chip and the base member.

### BRIEF DESCRIPTION OF THE DRAWINGS

FIGS. 1A and 1B are schematic cross-sectional views showing a semiconductor device according to an embodiment;

FIG. 2A to FIG. 4B are schematic cross-sectional views showing a manufacturing process of the semiconductor device according to the embodiment;

FIG. 5 is a schematic cross-sectional view showing a bonding structure of the semiconductor device according to the embodiment; and

FIGS. 6A to 6C are schematic cross-sectional views showing a manufacturing process of the semiconductor device according to a modification of the embodiment.

### DETAILED DESCRIPTION

According to one embodiment, a method for manufacturing a semiconductor device includes forming a bonding layer on a back-surface of a semiconductor element, mounting the semiconductor element on a base member, and bonding the semiconductor element to the base member by pressing the semiconductor element on the base member. The bonding layer includes tin. The base member includes a plating layer that includes silver and tin. The base member is heated at a prescribed temperature. The semiconductor element is placed on the base member so that the bonding layer contacts the plating layer on the base member.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

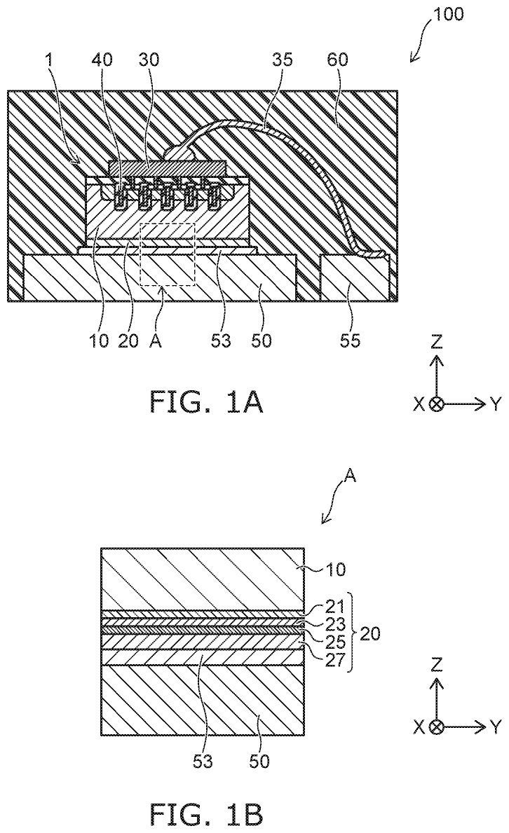

FIGS. 1A and 1B are schematic cross-sectional views showing a semiconductor device 100 according to an embodiment. FIG. 1A is a schematic view showing a cross section of the semiconductor device 100. FIG. 1B is an enlarged cross-sectional view schematically showing the region A in FIG. 1A.

As shown in FIG. 1A, the semiconductor device 100 includes a semiconductor element 1. The semiconductor element 1 is, for example, a MOSFET. Moreover; the semiconductor element 1 is not limited to this example, and may be, for example, a diode or an IGBT (Insulated Gate Bipolar Transistor).

The semiconductor element 1 includes, for example, a semiconductor part 10, a drain electrode 20, a source electrode 30 and a gate electrode 40. The semiconductor part 10 is, for example, silicon, and the drain electrode 20 is provided on the back-surface of the semiconductor part 10. The source electrode 30 is provided at the front surface side of the semiconductor part 10. The gate electrode 40 is provided between the semiconductor part 10 and the source electrode 30. The gate electrode 40 has, for example, a trench gate structure.

The semiconductor element 1 is mounted on the base plate 50, for example. The base plate 50 is electrically connected to the semiconductor element 1 at the back-surface side thereof via, for example, a bonding member 53. The base plate 50 is, for example, copper (Cu) or copper alloy with plate-like shape. The bonding member 53 is a plated layer formed on the front surface of the base plate 50. The bonding member 53 includes, for example, silver (Ag) and tin (Sn).

The semiconductor element 1 is electrically connected to a source terminal 55 through, for example, a metal wire 35. The metal wire 35 is bonded on the source electrode 30.

The semiconductor element 1 is sealed with, for example, a resin member 60. The resin member 60 is, for example, epoxy resin or silicone which is molded to cover the semiconductor element 1, the metal wire 35, the base plate 50 and the source terminal 55.

As shown in FIG. 1B, the drain electrode 20 includes, for example, a titanium (Ti) layer 21, a nickel (Ni) layer 23, a silver (Ag) layer 25, and a tin (Sn) layer 27. The titanium layer 21, the nickel layer 23, the silver layer 25, and the tin layer 27 are stacked in order on the back-surface of the semiconductor part 10. The titanium layer 21 is in contact with the semiconductor part 10 and electrically connected thereto. The tin layer 27 is in contact with the bonding member 53 and electrically connected thereto. For example, the nickel layer 23 suppresses the oxidization of the titanium layer 21 and a reaction between the titanium layer 21 and the silver layer 25 or the tin layer 27. Moreover, it is possible to improve the adhesion of the silver layer 25 by interposing the nickel layer 23 as compared with the case where the silver layer 25 is provided directly on the titanium layer 21.

In the manufacturing method according to the embodiment, the bonding strength of the semiconductor element 1 to the base plate 50 is improved by making the tin layer 27 contact to the bonding member 53 which includes silver and tin. That is, the bonding member 53 including silver and tin has a high affinity for the tin layer 27. Therefore, it is possible to mount the semiconductor element 1 on the base plate 50 with a preferable reproducibility, and thus, the reliability of the semiconductor device 100 is improved.

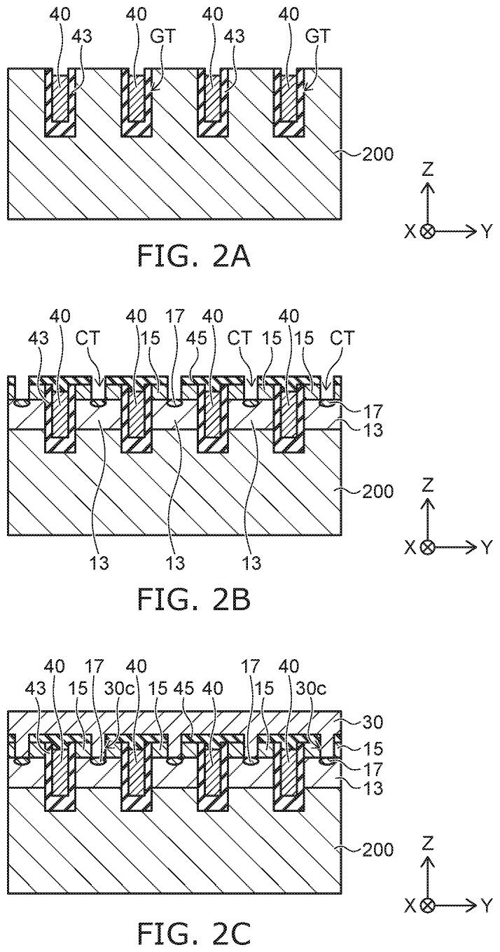

Hereinafter, with reference to FIGS. 2A to 4B, a manufacturing method of the semiconductor device 100 will be described. FIGS. 2A to 4B are schematic cross-sectional views showing the manufacturing process of the semiconductor device 100 according to the embodiment.

As shown in FIG. 2A, a gate electrode 40 having a trench gate structure is formed at the front surface side of a wafer 200. The wafer 200 is, for example, an n-type silicon wafer. The gate electrode 40 is provided in a gate trench GT via a gate insulating film 43 after the gate insulating film 43 is formed on the inner surface of the gate trench GT. The gate insulating film 43 is, for example, a silicon oxide film formed by thermal oxidization. The gate electrode 40 is, for example, conductive polysilicon.

As shown in FIG. 2B, a p-type diffusion layer 13, an n-type source layer 15, and a p-type contact layer 17 are formed at the front surface side of the wafer 200.

The p-type diffusion layer 13 is formed at the front surface side of the wafer 200 by, for example, ion-implanting a p-type impurity, and then activating and diffusing the p-type impurity through a heat treatment. The p-type impurity is, for example, boron (B).

The n-type source layer 15 is formed, for example, by heat-treating the wafer 200 after ion-implanting an n-type impurity at the front surface side of the p-type diffusion layer 13. The n-type impurity is, for example, phosphorus (P),

Subsequently, after an interlayer insulating film 45 is formed to cover the gate electrode 40, a contact trench CT is formed. The interlayer insulating film 45 is, for example, a silicon oxide film formed by CVD (Chemical Vapor Deposition). For example, the contact trench CT is formed to extend through the interlayer insulating film 45 and the n-type source layer 15 and reach the p-type diffusion layer 13.

Further, a p-type contact layer 17 is formed by selectively ion-implanting a p-type impurity through the bottom of the contact trench CT. The p-type contact layer 17 is formed, for example, by heat-treating the wafer 200 in which the p-type impurity is ion-implanted into the p-type diffusion layer 13. The p-type impurity is, for example, boron (B).

As shown in FIG. 2C, the source electrode 30 is formed at the front surface side of the wafer 200. The source electrode 30 is a metal layer including, for example, tungsten and aluminum. The source electrode 30 includes a contact portion 30c. The contact portion 30c contacts the n-type source layer 15 and the p-type contact layer 17, and is electrically connected thereto in the contact trench CT.

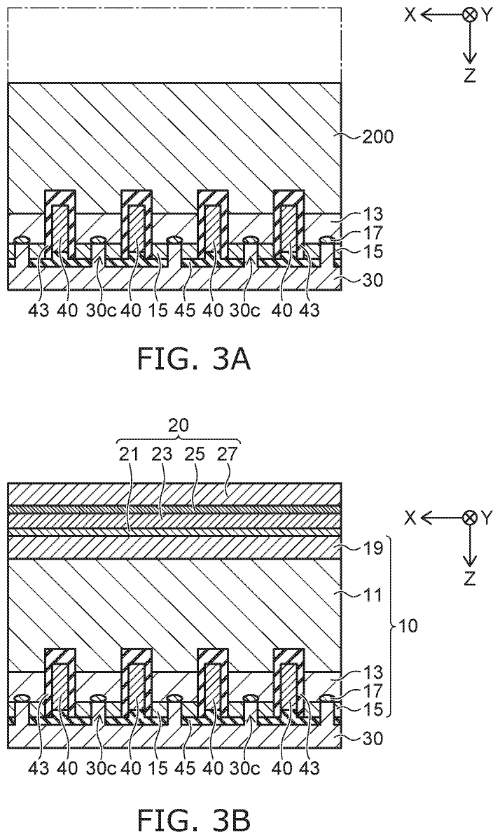

As shown in FIG. 3A, the wafer 200 is ground or etched at the back-surface side after the MOS (Metal Oxide Semiconductor) structure is formed at the front surface side thereof. The wafer 200 is thinned to have a desired chip thickness.

As shown in FIG. 3B, after an n-type drain layer 19 is formed at the back-surface side of the wafer 200, the drain electrode 20 is formed thereon. The n-type drain layer 19 is formed, for example, by ion-implanting an n-type impurity at the back-surface side of the wafer 200 and performing a heat treatment. The n-type impurity is, for example, phosphorus (P)

The drain electrode 20 includes, for example, the titanium layer 21, the nickel layer 23, and the silver layer 25, which are sequentially stacked using a sputtering method. The titanium layer 21 and the nickel layer 23 each have a thickness of, for example, several dozen nanometers. The silver layer 25 has a thickness of, for example, several hundred nanometers. Further, the drain electrode 20 includes the tin layer 27 formed on the silver layer 25. The tin layer 27 is formed by using, for example, a vacuum evaporation method, and has a thickness of several micrometers in the stacking direction (e.g., the Z-direction).

The wafer 200 is the semiconductor part 10 after being thinned. The semiconductor part 10 includes an n-type drift layer 11, the p-type diffusion layer 13, the n-type source layer 15, the p-type contact layer 17 and the n-type drain layer 19. The n-type drift layer 11 is provided between the p-type diffusion layer 13 and the n-type drain layer 19.

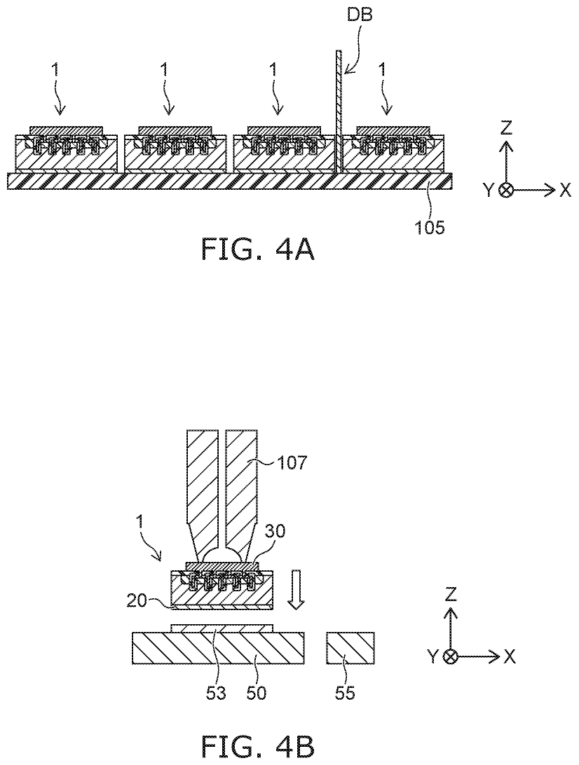

As shown in FIG. 4A, for example, a dicing sheet 105 is attached to the thinned wafer 200 for dicing. The semiconductor elements 1 are formed into chips by cutting the wafer 200 using, for example, a dicing blade DB.

As shown in FIG. 4B, the semiconductor element 1 is stuck to, for example, a collet 107 by vacuum suction and picked up from the dicing sheet 105. Subsequently, the semiconductor element 1 is transferred to the base plate 50 and mounted thereon while being vacuum suctioned to the collet 107.

The base plate 50 and the source terminal 55 are, for example, parts of a copper lead frame. A plating layer including silver and tin (i.e., the bonding member 53) is formed on the front surface of the base plate 50.

The semiconductor element 1 is mounted and pressed on the base plate 50 so that the drain electrode 20 and the bonding member 53 are in contact with each other, while the base plate 50 is heated up to a prescribed temperature. The semiconductor element 1 is bonded thereby to the base plate 50.

Subsequently, a metal wire 35 is bonded to the source electrode 30 of the semiconductor element 1, and electrically connects the semiconductor element 1 and the source terminal 55 (see FIG. 1A). Further, after the resin member 60 is molded over the lead frame on which the semiconductor element 1 is mounted, the lead frame and the resin member 60 are cut to complete the semiconductor device 100.

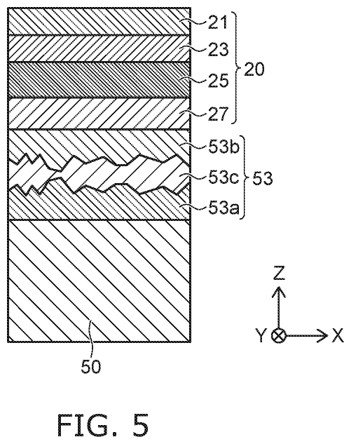

FIG. 5 is a schematic cross-sectional view showing a bonding structure of the semiconductor device 100 according to the embodiment, FIG. 5 is a schematic sectional view corresponding to the region A in FIG. 1A. FIG. 5 is a schematic view showing a bonding structure formed through the manufacturing process described above.

As shown in FIG. 5, the bonding member 53 includes, for example, a copper-silver eutectic alloy 53a, a silver-tin eutectic alloy 53b and a plating layer 53c. The plating layer 53c includes silver and tin. The copper-silver eutectic alloy 53a is formed by a reaction between the plating layer 53c and the base plate 50. The silver-tin eutectic alloy 53b is formed by a reaction between the tin layer 27 of the drain electrode 20 and the plating layer 53c. The unreacted region of the plating layer 53c remains between the copper-silver eutectic alloy 53a and the silver-tin eutectic alloy 53b.

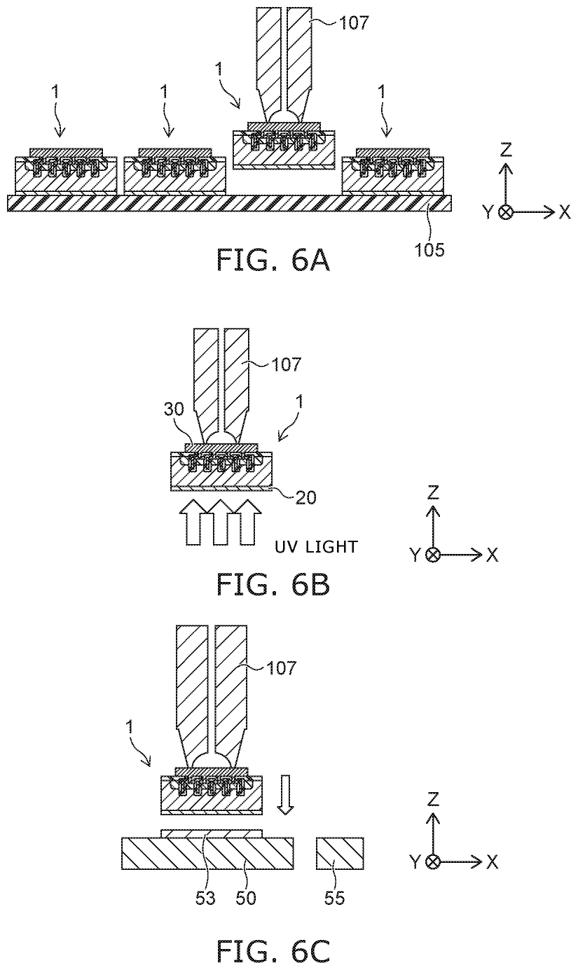

FIGS. 6A to 6C are schematic cross-sectional views showing a manufacturing process of the semiconductor device 100 according to a modification of the embodiment. FIGS. 6A to 6C are schematic views showing manufacturing steps which follow the step in FIG. 4A.

As shown in FIG. 6A, the chip-shaped semiconductor element 1 is stuck to the collet 107 by vacuum suction and picked up from the dicing sheet 105.

As shown in FIG. 6B, for example, while being transferred from the dicing sheet 105 to the lead frame, the back-surface of the semiconductor element 1 is irradiated with ultraviolet light (UV light). UV light is, for example, laser light emitted by Excirner laser. The embodiment is not limited to UV light, but visible light or infrared light may be used in place of UV light.

The surface of the drain electrode 20 can be activated by such light irradiation, which is provided on the back-surface of the semiconductor element 1. Here, “activation” means the heated temperature at the drain electrode 20 or the improved affinity for the bonding member 53 by, for example, removing hydrogen or moisture adsorbed on the surface of the tin layer 27.

As shown in FIG. 6C, the semiconductor element 1 is mounted on the base plate 50 heated up to a prescribed temperature. The semiconductor element 1 is mounted on the base plate 50, for example, immediately after being irradiated with UV light. The semiconductor element 1 is pressed by the collet 107 while the drain electrode 20 is in contact with the bonding member 53.

In this example, the surface affinity of the drain electrode 20 is improved for the bonding member 53 by irradiating the drain electrode 20 with light irradiation and activating the surface thereof. Thereby, it is possible to further improve the bonding strength of the semiconductor element 1 and the base plate 50. The embodiment is not limited to this example. For example, there may be the case where the bonding member 53 is activated by the light irradiation.

The embodiment is not limited to the above-described examples. For example, the bonding member 53 may be an alloy including lead (Pb).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention,

What is claimed is:

1. A method for manufacturing a semiconductor device, the method comprising:
forming a bonding layer on a back-surface of a semiconductor element, the bonding layer including tin;
mounting the semiconductor element on a base member, the base member including a plating layer and being heated at a prescribed temperature, the plating layer including silver and tin, the semiconductor element being placed on the base member so that the bonding layer contacts the plating layer on the base member; and
bonding the semiconductor element to the base member by pressing the semiconductor element on the base member.

2. The method according to claim 1, wherein
the base member includes copper, and
the plating layer is selectively formed on the base member.

3. The method according to claim 1, wherein
the bonding layer of the semiconductor element includes a first layer and a second layer, the first layer being in contact with the back-surface and being electrically connected to the semiconductor element, the first layer including metal other than tin, the second layer including tin, and
the first layer and the second layer are stacked in order on the back-surface, the second layer contacting the plating layer when the semiconductor element is mounted on the base member.

4. The method according to claim 3, wherein
the bonding layer further includes a third layer provided between the first layer and the second layer, the third layer including nickel.

5. The method according to claim 4, wherein
the bonding layer further includes a fourth layer provided between the third layer and the second layer, the fourth layer including silver.

6. The method according to claim 1, wherein
a first eutectic region is formed between the bonding layer and the plating layer,
a second eutectic region is formed between the base member and the plating layer, and
the semiconductor element is bonded to the base member so that a portion of the plating layer remains between the first eutectic region and the second eutectic region.

7. The method according to claim 6, wherein
the first eutectic region includes silver and tin, and
the second eutectic region includes silver and metal included in the base member.

8. The method according to claim 1, wherein
the semiconductor element is mounted on the base member after the bonding layer of the semiconductor element or the plating layer on the base member is irradiated with light.

9. The method according to claim 8, wherein
the bonding layer of the semiconductor element is irradiated with ultraviolet light.

10. The method according to claim 8, wherein
the bonding layer of the semiconductor element is irradiated with visible light.
